(19) United States
(12) Patent Application Publication
(10) Pub. No.: US 2010/0047539 A1
(43) Pub. Date: Feb. 25, 2010

(54) POSITIVE PHOTOSENSITIVE RESIN COMPOSITION, METHOD OF FORMING PATTERN AND SEMICONDUCTOR DEVICE

(75) Inventors: Joohyeon Park, Cheonan-si (KR); Kyungchul Son, Gangneung-si (KR); Junghwan Cho, Yeonje-gu (KR)

Correspondence Address: HAMMER & ASSOCIATES, P.C., 3125 SPRINGBANK LANE, SUITE G, CHARLOTTE, NC, 28226, US

(73) Assignee: Korea Kumho Petrochemical Co., Ltd.

(21) Appl. No.: 12/276,443

(22) Filed: Nov. 24, 2008

(30) Foreign Application Priority Data
Aug. 25, 2008 (KR) 10-2008-0082809

(51) Int. Cl. B32B 3/10; G03F 7/004; G03F 7/20

(52) U.S. Cl. 428/201; 430/270.1; 430/283.1; 430/286.1; 430/326; 428/195.1

(57) ABSTRACT

Disclosed are a positive photosensitive resin composition, a method of forming a pattern using the same, and a semiconductor device having a photoresist pattern obtained by the method. The composition for positive photosensitive resin comprises a polyamide derivative, a photosensitive compound, and at least one additive having a low molecular weight.

### CROSS-REFERENCE TO RELATED APPLICATION

This application claims the benefit of Korean Patent Application No. 10-2008-0082809, filed on Aug. 25, 2008, in the Korean Intellectual Property Office, the disclosure of which is incorporated herein by reference.

### BACKGROUND OF THE INVENTION

1. Field of the Invention

The present invention relates to a photosensitive resin composition and a method of forming a pattern using the same, and more particularly, to a positive photosensitive resin composition, a method of forming a pattern using the same, and a semiconductor device having a photoresist pattern obtained by the method.

2. Description of Related Art

According to prior arts, polyimide resin having superior heat resistance, electric characteristics, mechanical characteristics, and the like has been used as an interlayer dielectric or passivation layer of semiconductor devices and/or display apparatuses. In general, the polyimide resin may be obtained such that a photosensitive polyimide composition is coated on a substrate, and the coated composition is exposed, developed, and heated.

However, since the photosensitive polyimide composition is vulnerable to thermal stability, a pattern of the polyimide resin may be damaged while performing cross-linking at about 350° C., or a volume of the pattern may be significantly reduced. In order to overcome the above-mentioned problems, a cross-linking agent having superior thermal stability may be added to the photosensitive polyimide composition. In this case, disadvantageously, a resolution of the pattern may be reduced due to the cross-linking agent, or a degree of cross-linking between molecules is significantly high during the cross-linking procedure, thereby reducing flexibility of the polyimide resin.

Also, sensitivity of the photosensitive polyimide composition is important when forming a pattern using the photosensitive polyimide composition. When the sensitivity thereof is relatively low, an exposure time may increase, thereby reducing the throughput. However, when a large volume of photosensitizer and the like is added to the photosensitive polyimide composition in order to improve the sensitivity thereof, the sensitivity may become high, but a scum phenomenon in which surplus is generated at ends of the pattern after developing may occur.

### SUMMARY OF THE INVENTION

An aspect of the present invention provides a positive photosensitive resin composition that may have high sensitivity and minimize scum generation, a method of forming a pattern using the positive photosensitive resin composition, and a semiconductor device having a photoresist pattern obtained by the method of forming the pattern.

An aspect of the present invention provides a positive photosensitive resin composition that may have excellent uniformity and resolution and minimize shrinkage at the time of performing cross-linking, a method of forming a pattern using the positive photosensitive resin composition, and a semiconductor device having a photoresist pattern obtained by the method of forming the pattern.

According to an aspect of the present invention, there is provided a positive photosensitive resin composition including a polyamide derivative, a photosensitive compound, and at least one additive having a low molecular weight.

In this instance, the positive photosensitive resin composition may further include a surfactant and an agent for improving adhesiveness.

Also, the polyamide derivative may be represented by

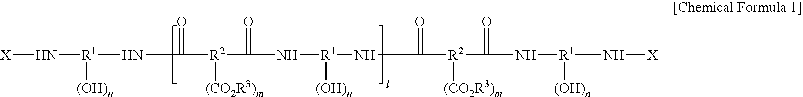

wherein R¹ and R² are independently selected from organic group (II) to organic group (VI) each with 2 or more carbon atoms, R³ is selected from H and a C₁₋₁₀ organic group, l is an integer of 10 to 1,000, n and m are independently selected from integers of 0 to 2, in which n+m>0, and X is selected from H and a C₂₋₃₀ organic group.

Also, the photosensitive compound may be a diazonaphthol compound. The diasonaphthol compound may be represented by

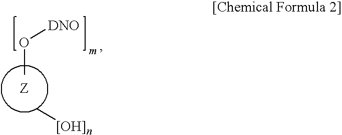

wherein n and m are independently selected from integers of 0 to 5, in which n+m>0,

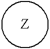

is a C₁₂₋₄₀ aryl group, and DNQ(diazonaphthoquinone) is

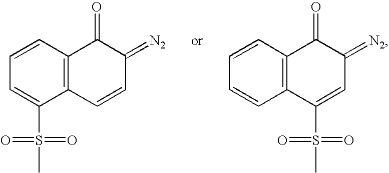

Also, the additive may be selected from chemical formulas 3 to 6 below. These additives may be used alone or in any combination thereof.

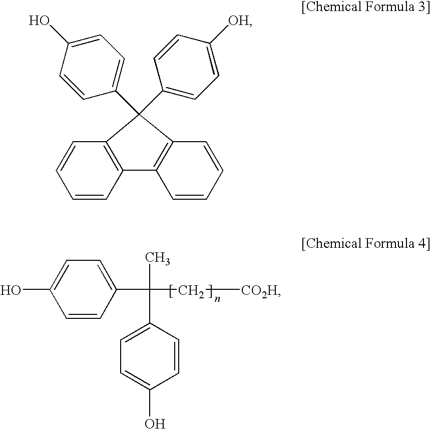

wherein n is an integer of 2 to 6,

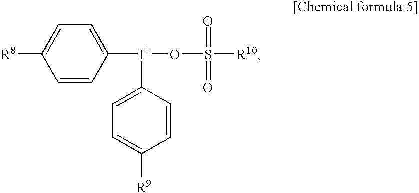

wherein R⁸ and R⁹ are independently selected from H and C₁₋₁₀ organic group, and R¹⁰ is a C₁₋₂₀ alkyl group or a C₁₋₂₀ aryl group, and

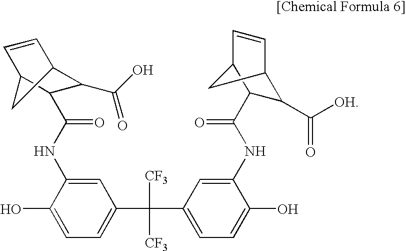

According to an aspect of the present invention, there is provided a method of forming a pattern, including coating the composition for the positive photosensitive resin on a substrate, and drying the coated composition to form a photoresist layer; selectively exposing the photoresist layer; developing the exposed photoresist layer to form a photoresist pattern; and heating the photoresist pattern.

According to an aspect of the present invention, there is provided a semiconductor having the photoresist pattern obtained by the method of forming the pattern acting as an interlayer dielectric or passivation layer.

### BRIEF DESCRIPTION OF THE DRAWINGS

The above and other aspects of the present invention will become apparent and more readily appreciated from the following detailed description of certain exemplary embodiments of the invention, taken in conjunction with the accompanying drawings of which:

FIG. 1 is a photograph showing ¹H-NMR of a compound manufactured according to synthesis example 9; and

FIG. 2 is a photograph showing ¹H-NMR of a compound manufactured according to synthesis example 10.

### DETAILED DESCRIPTION OF EXEMPLARY EMBODIMENTS

Hereinafter, a positive photosensitive resin composition according to exemplary embodiments of the invention, a method of forming a pattern using the positive photosensitive resin composition, and a semiconductor device having a photoresist pattern obtained by the method of forming the pattern will be described in detail.

The positive photosensitive resin composition according to the present exemplary embodiment includes a polyamide derivative, a photosensitive compound, and at least one low molecular weight additive. Also, the positive photosensitive resin composition according to the present exemplary embodiment may further include an agent for improving adhesiveness, a surfactant, and a solvent. Also, the positive photosensitive resin composition according to the present exemplary embodiment may further include a defoamer for removing air bubbles.

The polyamide derivative may be represented as

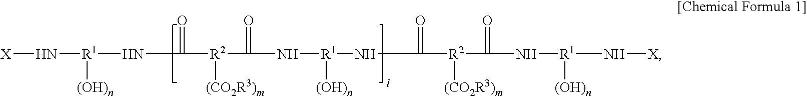

wherein R¹ and R² are independently selected from organic group (II) to organic group (VI) each with 2 or more carbon atoms, R³ is selected from H and a C₁₋₁₀ organic group, l is an integer of 10 to 1,000, n and m are independently selected from integers of 0 to 2, in which n+m>0, and X is selected from H and a C₂₋₃₀ organic group.

A structure represented as R¹ in Chemical Formula 1 may be selected from chemical formulas below, however the present invention is not limited thereto. The chemical formulas below may be used alone or in any combination thereof.

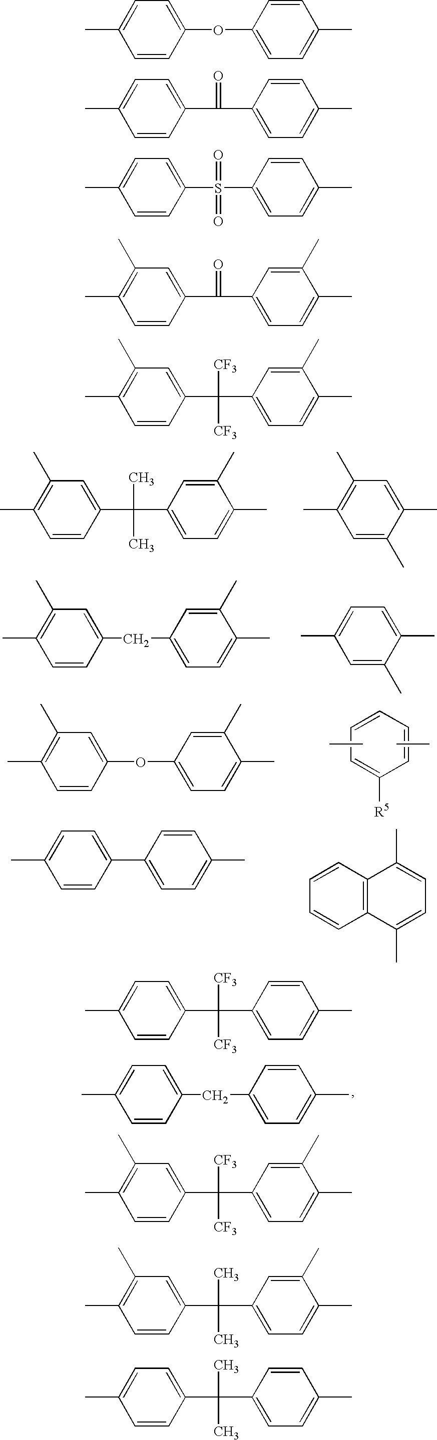

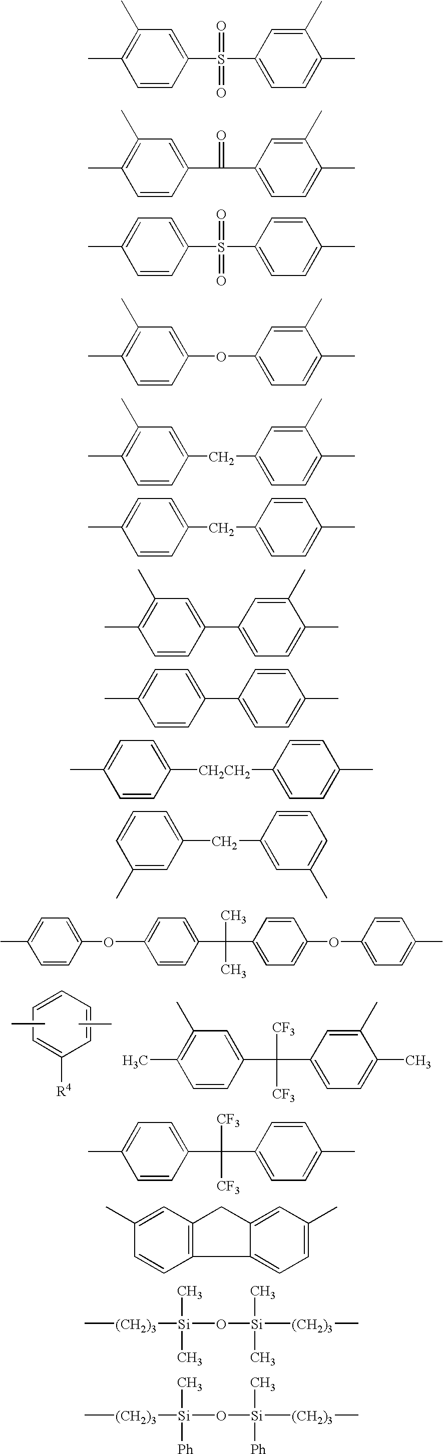

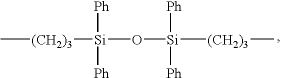

wherein R⁴ is selected from H, halogen, a hydroxy group, a carboxyl group, a thiol group and a C₁₋₁₀ organic group. In this instance, the organic group may or may not include a functional group.

A structure represented as R² in Chemical Formula 1 may be selected from chemical formulas below, however the present invention is not limited thereto. The chemical formulas below may be used alone or in any combination thereof.

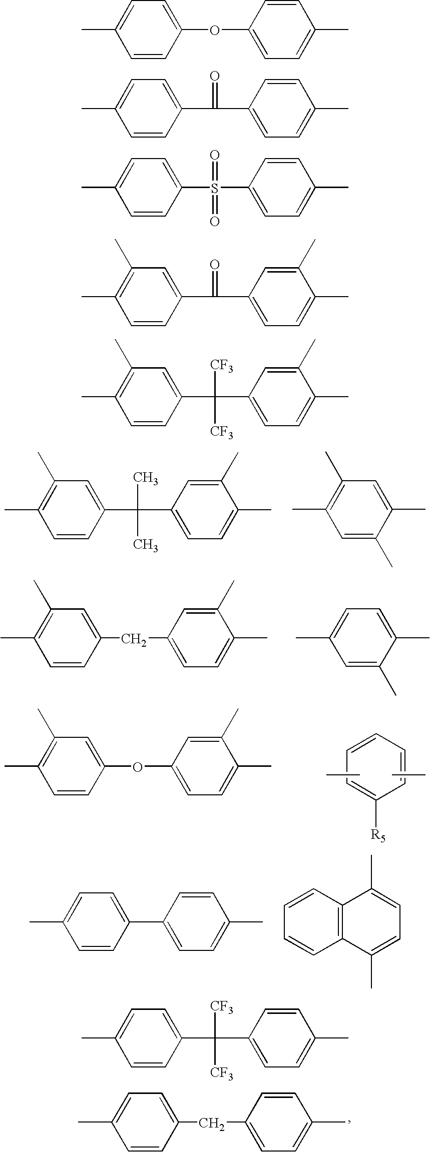

wherein R⁵ is selected from H, halogen, a hydroxy group, an ether group, a thiol group and a C₁₋₁₀ organic group. In this instance, the organic group may or may not include a functional group.

A structure represented as X in Chemical Formula 1 may be selected from chemical formulas below, however the present invention is not limited thereto. The chemical formulas below may be used alone or in any combination thereof.

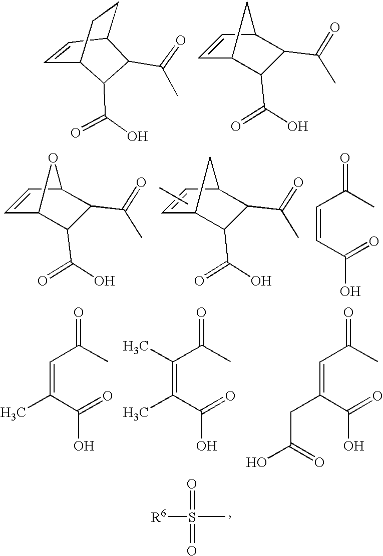

wherein R⁶ is a C₁₋₁₀ organic group comprising an alkyl group or an aryl group. In this instance, the organic group may or may not include a functional group.

The polyamide derivative represented as Chemical Formula 1 may be generally manufactured by a condensation reaction. Specifically, a dicarboxylic acid derivative may be converted into a dichloride derivative using thionyl chloride, and the converted dichloride derivative is subjected to a condensation reaction with a diamine derivative under a basic catalysis to thereby manufacture the polyamide derivative. A reaction temperature of the condensation reaction may not be particularly limited, but preferably is about 80° C. or less. When the reaction temperature thereof is too high, a development rate or UV transmittance may be deteriorated due to creation of by-products. However, when the reaction temperature is −10° C. or less, the reaction rate is disadvantageously reduced. Accordingly, the condensation reaction may be preferably performed at about −10° C. to 80° C. Then, the reaction mixture is gradually dropped and precipitated in pure water after terminating the condensation reaction, and a desirable polyamide derivative of solid particles may be obtained. When a molecular weight of the polyamide derivative is high, an amount of an acid anhydride derivative or a sulfonyl chloride derivative used for reacting with an amine functional group may increase.

As for synthesizing the polyamide derivative represented as Chemical Formula 1, a functional group being chemically stable may be substituted for an amine group of a polymer main chain in order to control the molecular weight and improve storage stability of products. A method for substituting another functional group for the amide group is not specifically limited, however, for example, the amine group may be reacted with a compound that may enable generation of an amide group by reacting with the amine group. The compound is not specifically limited, and an alkylcarbonyl chloride derivative, an alkenylcarbonyl chloride derivative, an alkynylcarbonyl chloride derivative, an alkylsulfonyl chloride derivative, an arylsulfonyl chloride derivative, acid anhydride derivatives including an alkyl, aryl group or alkenyl group, and the like may be used alone or in any combination thereof.

The photosensitive compound is not specifically limited, and a diazonaphthol compound, a diazoquinone compound, and the like may be used alone or in any combination thereof.

The diazonaphthol compound may be represented as

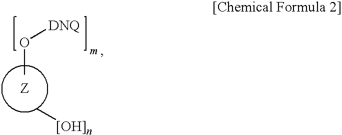

wherein n and m are independently selected from integers of 0 to 5, in which n+m>0,

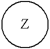

is a C₁₂₋₄₀ aryl group, and DNQ is

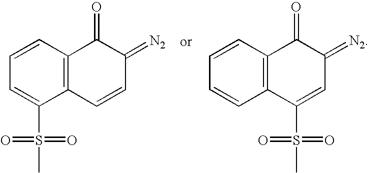

The diazonaphthol compound may be obtained such that a phenol derivative including at least two hydroxy groups and a diazonaphtholsulfonyl chloride derivative are reacted under an amine catalyst. In this case, when the DNQ is substituted for all hydroxy groups, solubility with respect to a solvent is reduced, and thereby crystal grain may be created after manufacturing. Thus, a substitution degree of the DNQ with respect to the hydroxy groups of the phenol derivative may be about 70 to 95%, however, the present invention is not limited thereto. As an example, when the solubility with respect to the solvent is superior, a diazonaphthol compound in which DNQ is completely substituted for the hydroxy groups of the phenol derivative may be used. Also, when the DNQ of 70% or less is substituted for the hydroxy groups thereof, an affinity for the diazonaphthol compound and a developing solution may increase, and accordingly results in a significant reduction in a thickness at the time of forming the pattern. Phenol derivative without absorption at about 365 nm may be preferably employed when an i-line exposure is used upon forming the pattern using the positive photosensitive resin composition according to the present exemplary embodiment. When the pattern has a high absorption at about 365 nm, the verticality of the pattern is inferior.

The diazonaphthol compound represented as Chemical Formula 2, for example, may be selected from chemical formulas below, however the present invention is not limited thereto. The chemical formulas below may be used alone or in any combination thereof.

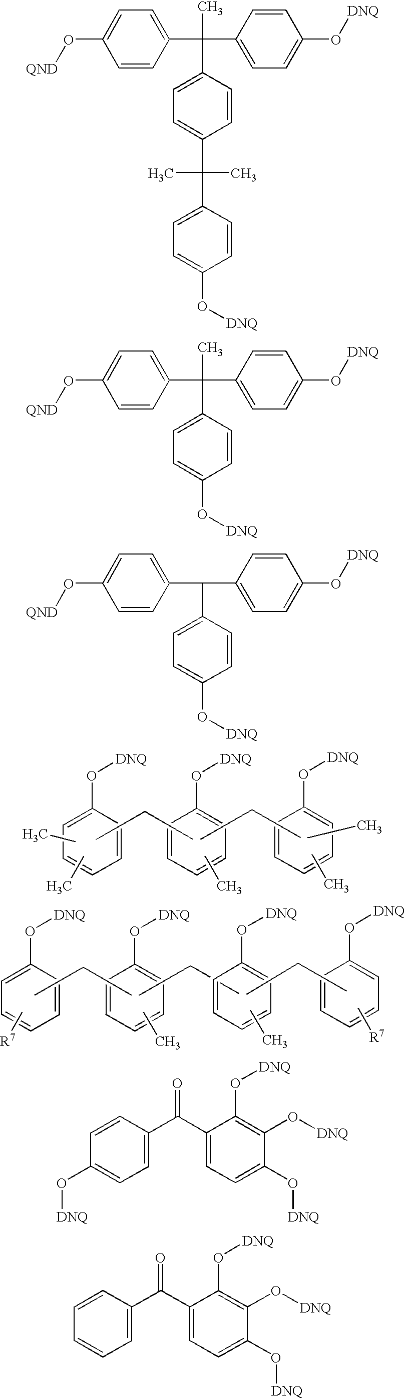

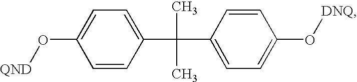

wherein DNQ is H,

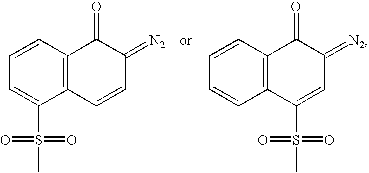

each of the diazonaphthol compound comprises at least one of

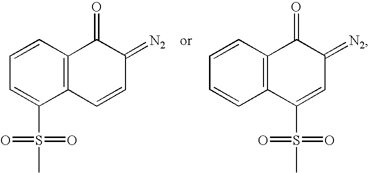

and R⁷ is selected from H, a methyl group and —O-DNQ group.

At least two or more of the above chemical formulas of the diazonaphthol compound may be used, as necessary. Benzophenone derivative included in the diazonaphthol compound is superior in sensitivity, but is inferior in verticality of the pattern. However, in a case where a small amount of the benzophenone derivative is contained in the diazonaphthol compound, the sensitivity is slightly improved. In general, 1,2-naphthoquinone-2-diazide-4-sulfonic acid ester derivative has superior UV-sensibility than 1,2-naphthoquinone-2-diazide-5-sulfonic acid ester derivative.

The photosensitive compound such as the diazonaphthol compound may be 5 to 30 parts by weight based on 100 parts by weight of the polyamide compound. When the photosensitive compound is 5 parts or less by weight based on 100 parts by weight of the polyamide compound, a dissolution retarding effect against the developing solution is insufficient, and encounters difficulties in forming the pattern. Conversely, when the photosensitive compound is 30 parts or more by weight based thereon, a thickness loss rate of the film after performing thermal cross-linking is significantly high.

The additive may be selected from Chemical Formulas 3 to 6. Chemical Formulas 3 to 6 may be used alone or in any combination thereof.

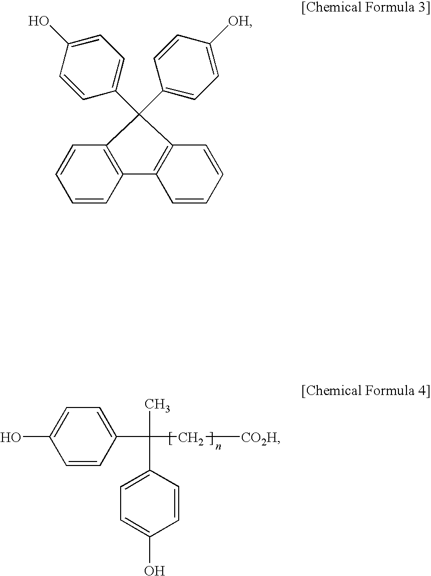

wherein n is an integer of 2 to 6,

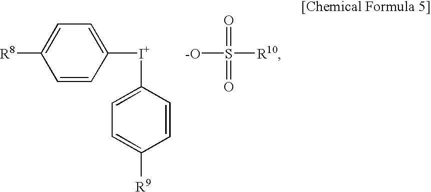

wherein R⁸ and R⁹ are independently selected from H and C₁₋₁₀ organic group, and R¹⁰ is a C₁₋₂₀ alkyl group or a C₁₋₂₀ aryl group, and

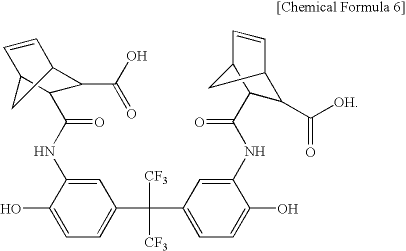

Upon forming the pattern using the positive photosensitive resin composition according to the present invention, the additive may achieve high resolution and high sensitivity, and minimize a change in the thickness after performing the thermal cross-linking while preventing other physical properties from being deteriorated. Also, upon forming the pattern using the same, the additive may achieve superior thermal stability, and improve flexibility of the pattern after performing the thermal cross-linking.

Specifically, upon forming the pattern using the same, the additive represented as Chemical Formula 3, that is, bis(4-hydroxy)fluorine, may prevent non-exposed parts from being dissolved in a developing solution after exposing, and increase thermal stability after the pattern is hardened.

The additive represented as Chemical Formula 4, that is, 4,4-bis(4-hydroxyphenyl) valeric acid or a derivative thereof, may control an amount of exposure energy upon forming the pattern, and increase a development rate of the exposed parts. Also, the additive represented as Chemical Formula 4 may prevent occurrence of scum, thereby increasing the resolution of the pattern.

The additive represented as Chemical Formula 5, that is, dipheyliodonium salts, may control an amount of exposure energy upon forming the pattern. The dipheyliodonium salts are not specifically limited, and dipheyliodonium camphorsulfonate or dipheyliodonium toluenesulfonate may be used as the dipheyliodonium salts. These may remarkably prevent the non-exposed parts from being melted in the developing solution.

The additive represented as Chemical Formula 6, that is, an amide compound of 2,2-bis(3-amino-4-hydroxyphenyl)hexafluoropropane and 5-norbornene-2,3-dicarboxylic anhydride may control an amount of exposure energy upon forming the pattern. The additive represented as Chemical Formula 6 may have similar effects as in Chemical Formula 4, and improve sensibility.

The amount of the additives represented as Chemical Formulas 3 to 6 may be 0.5 to 20 parts by weight based on 100 parts by weight of the polyamide compound. From these, the amount of the additive represented as Chemical Formula 4 may be 1 to 15 parts by weight based on 100 parts by weight of the polyamide compound. When the amount of the additive represented as Chemical Formula 4 is 1 part or less by weight based on 100 parts by weight of the polyamide compound, effects acquired due to addition of the additive are insignificant. Also, when the amount of the additive represented as Chemical Formula 4 is 15 parts or more by weight based on 100 parts by weight of the polyamide compound, the non-exposed parts are disadvantageously dissolved in the developing solution. Also, the amount of the additive represented as Chemical Formula 5 may be 0.1 to 10 parts by weight based on 100 parts by weight of the polyamide compound. When the amount of the additive represented as Chemical Formula 5 is 0.1 part or less by weight based on 100 parts by weight of the polyamide compound, effects acquired due to addition of the additive are insignificant. Also, when the amount of the additive represented as Chemical Formula 5 is 10 parts or more by weight based on 100 parts by weight of the polyamide compound, a dissolution retarding effect against the developing solution may be significant, but the sensitivity may be deteriorated.

The agent for improving adhesiveness may increase an adhesive strength between the substrate and the pattern upon forming the pattern using the positive photosensitive resin composition. The agent for improving adhesiveness is not specifically limited, and for example, a silane coupling agent may be used as the agent. In addition, diaminosiloxane of 5% or less may be used in a polymer main chain. In a case where diaminosiloxane monomer of 5% or more is used in the polymer main chain resulting in acting as the agent for improving adhesiveness, thermal resistance may be deteriorated.

As examples of the silane coupling agent, vinyltrimethoxysilane, [3-(2-aminoethylamino)propyl]trimethoxysilane, 3-aminopropyltrimethoxysilane, N-methylaminopropyltrimethoxysilane, 3-glycidoxypropyltrimethoxysilane, 3-glycidoxypropyltriethoxysilane, 2-(3,4-epoxycyclohexyl)ethyltrimethoxysilane, 3-methacryloxypropyltrimethoxysilane, 3-mercaptopropyltrimethoxysilane, N-(1,3-dimetheylbutylidene)-3-(triethoxysilane)-1-propanamine, N,N-bis(3-trimethoxysilyl) propylethylamine, N-(3-trimethoxysilylpropyl)pyrrole, ureidopropyltrimethoxysilane, (3-triethoxysilylpropyl)-t-butylcarbamate, N-phenylaminopropyltrimethoxysilane, and 3-isocyanatepropyltrimethoxysilane may be given. These may be used alone or in any combination thereof. From these, preferably, 3-glycidoxypropyltrimethoxysilane, 3-glycidoxypropyltriethoxysilane, ureidopropyltrimethoxysilane, and the like may be used alone or in any combination thereof.

An amount of the silane coupling agent, that is, the agent for improving adhesiveness, may be 0.5 to 10 parts by weight based on 100 parts by weight of the polyamide compound. When the amount of the silane coupling agent is 0.5 part or less by weight based thereon, the adhesive strength may be deteriorated. Also, when the amount of the same is 10 parts by weight based thereon, formation of the pattern is inhibited, or scum may occur.

The surfactant may improve coating properties of the positive photosensitive resin composition according to the present invention. Polyether may be used as the surfactant, however, the surfactant is not limited thereto and a variety of surfactants may be used. An amount of the surfactant may be 0.005 to 0.05 parts by weight based on 100 parts by weight of the polyamide compound.

The solvent may be provided as a composition type obtained by melting or dissolving constituents of the positive photosensitive resin composition according to the present invention. The solvent is not specifically limited, and γ-butyrolactone, N-methylpyrrolidone, N,N-dimethylacete amide, dimethylsulphoxide, cyclohexane, 2-heptanone, propylene glycol monometheyl ether acetate, methyl isobutyl ketone, ethylene glycol dimethyl ether, ethylene glycol diethyl ether, ethyl lactate, and the like may be used alone or in any combination thereof.

As described above, the positive photosensitive resin composition may have high sensitivity and minimize scum occurrence. In addition, the positive photosensitive resin composition may have excellent coating uniformity and resolution, and minimize shrinkage at the time of performing cross-linking.

In order to form the pattern using the positive photosensitive resin composition according to the present invention, the positive photosensitive resin composition is coated on the substrate, and dried to form a photoresist layer. Next, the photoresist layer is selectively exposed, and the exposed photoresist layer is developed to thereby form a photoresist pattern. Next, the photoresist pattern is heated to thereby form the pattern. Hereinafter, the procedure of forming the pattern will be described in detail in a stepwise manner.

First, the positive photosensitive resin composition according to the present invention is coated, in a desired thickness, on a substrate used for manufacturing a semiconductor device, for example, a silicon wafer, or another substrate used for manufacturing a display apparatus, for example, a glass substrate.

In coating, one of a spin coating method, spray coating method, and roll coating method may be used, however, a variety of coating methods may be used. Next, the substrate on which the positive photosensitive resin composition is coated is heated to about 50 to 150° C. using an oven, a hot plate, or ultra violet rays to dry the solvent, thereby forming the photoresist layer.

Next, the photoresist layer is selectively exposed using an i-line ray, h-line ray, or g-line ray exposure. In this instance, a photo mask having the same pattern as a desired pattern formed thereon may be used.

Next, the exposed photoresist layer is developed using a developing solution, and the developed layer is washed and dried to form a photoresist pattern. As the developing solution used for developing, a compound is not specifically limited as long as the compound has basic developing characteristics. For example, tetramethylammonium hydroxide may be used for the developing solution.

Next, the photoresist pattern is heated in an oven at about 350° C. or more for at least several tens of minutes in order to convert the photoresist pattern into polyimide or polybenzoxazole compound. The heated photoresist pattern may be used for an interlayer dielectric or passivation layer of a semiconductor device and/or a display. The interlayer dielectric or passivation layer may have superior heat resistance, electric characteristics, mechanical characteristics, and the like.

Hereinafter, the present invention will be described in detail by synthesis examples, examples, and comparative examples. It is to be understood, however, that these synthesis examples, examples, and comparative examples are for illustrative purpose only, and are not construed to limit the scope of the present invention.

In the synthesis examples below, an organic solvent having been subjected to a dehydration processing was used, and a polyamide derivative synthesis was performed under a nitrogen atmosphere.

### Synthesis Example 1

### 4,4′-oxybis(benzoyl chloride) Synthesis

60 g (0.2324 mol) of 4,4′-oxybis(benzoic acid) and 240 g of N-methylpyrrolidone (NMP) were added to 0.5 L of a flask having a mixer and a thermometer mounted thereon, and stirred and dissolved. Next, the flask was cooled to 0° C., and 110 g (0.9246 mol) of thionyl chloride was dropped and reacted for one hour to acquire a 4,4′-oxybis(benzoyl chloride).

### Synthesis Example 2

### dimethyl-3,3′,4,4′-diphenylether-tetracarboxylate dichloride Synthesis

60 g (0.1934 mol) of 3,3′,4,4′-diphenylether-tetracarboxylic acid dianhydride, 24 g (0.3993 mol) of isopropyl alcohol, 2 g (0.0198 mol) of triethylamine, and 120 g of N-methylpyrrolidone (NMP) were added to 1 L of a flask having a mixer and a thermometer mounted thereon, and mixed at room temperature for four hours to manufacture a di-n-methyl-3,3′,4,4′-diphenylether-tetracarboxylate solution. Next, the flask was cooled to 0° C., and 70 g (0.5884 mol) of thionyl chloride was dropped, and reacted for two hours to acquire a dimethyl-3,3′,4,4′-diphenylether-tetracarboxylate dichloride solution.

### Synthesis Example 3

### diisopropyl-3,3′,4,4′-diphenylether-tetracarboxylate dichloride Synthesis

60 g (0.1934 mol) of 3,3′,4,4′-diphenylether-tetracarboxylic acid dianhydride, 24 g (0.3993 mol) of isopropyl alcohol, 2 g (0.0198 mol) of triethylamine, and 120 g of N-methylpyrrolidone (NMP) were added to 1 L of a flask having a mixer and a thermometer mounted thereon, mixed at room temperature for four hours to manufacture a diisopropyl-3,3′,4,4′-diphenylether-tetracarboxylate solution. Next, the flask was cooled to 0° C., and 70 g (0.5884 mol) of thionyl chloride was dropped and reacted for two hours to acquire a diisopropyl-3,3′,4,4′-diphenylether-tetracarboxylate dichloride solution.

### Synthesis Example 4

### Polyimide A Synthesis

400 g of N-methylpyrrolidone (NMP) and 85 g (0.2321 mol) of 2,2-bis(3-amino-4-hydroxyphenyl)hexafluoropropane were added to 1 L of a flask having a mixer and thermometer mounted thereon, mixed and dissolved. Next, 39 g (0.4930 mol) of pyridine was added to the flask and 8 g (0.0487 mol) of 5-norbornene-2,3-dicarboxylic anhydride and the 4,4′-oxybis(benzoyl chloride) synthesized through the synthesis example 1 were gradually dropped, and mixed at room temperature for one hour. The resultant solution was added to 3 L of water, and the resultant deposit was filtered, washed, and vacuum dried to acquire 128 g of a polyimide A. In this instance, the acquired polyimide A had a polystyrene-conversion average molecular weight of 18,500.

### Synthesis Example 5

### Polyimide B Synthesis

Synthesis example 5 was performed in the same way as synthesis example 4, except that 3 g (0.0097 mol) of 3,3′,4,4′-diphenylether-tetracarboxylic acid dianhydride was further added, thereby acquiring 120 g of polyimide B. In this instance, the acquired polyimide B had a polystyrene-conversion average molecular weight of 16,200.

### Synthesis Example 6

### Polyamidate C Synthesis

260 g of N-methylpyrrolidone (NMP) and 65 g (0.1775 mol) of 2,2-bis(3-amino-4-hydroxyphenyl) hexafluoropropane were added to 1 L of a flask having a mixer and thermometer mounted thereon, mixed and dissolved. Next, 35 g (0.4425 mol) of pyridine was added to the flask, and the dimethyl-3,3′,4,4′-diphenylether-tetracarboxylate dichloride solution synthesized through the synthesis example 2 was gradually dropped, and mixed at room temperature for one hour. The resultant solution was added to 3 L of water, and the resultant deposit was filtered, washed, and vacuum dried to acquire 128 g of a polyamidate C. In this instance, the acquired polyamidate C had a polystyrene-conversion average molecular weight of 19,200.

### Synthesis Example 7

### Polyamidate D Synthesis

260 g of N-methylpyrrolidone (NMP) and 65 g (0.1775 mol) of 2,2-bis(3-amino-4-hydroxyphenyl)hexafluoropropane were added to 1 L of a flask having a mixer and thermometer mounted thereon, mixed and melted. Next, 35 g (0.4425 mol) of pyridine was added to the flask, and the diisopropyl-3,3′,4,4′-diphenylether-tetracarboxylate dichloride NMP solution synthesized through the synthesis example 3 was gradually dropped for 30 minutes, and mixed at room temperature for one hour. The resultant solution was added to 3 L of water, and the resultant deposit was filtered, washed, and vacuum dried to acquire 119 g of polyamidate D. In this instance, the acquired polyamidate D had a polystyrene-conversion average molecular weight of 17,400.

### Synthesis example 8

### Polyamidate E Synthesis

2 g (0.0064 mol) of 3,3′,4,4′-diphenylether-tetracarboxylic acid dianhydride was added to the dimethyl-3,3′,4,4′-diphenylether-tetracarboxylate dichloride NMP solution synthesized through the synthesis example 2, and dissolved to manufacture a mixed solution. Next, 260 g of N-methylpyrrolidone (NMP) and 65 g (0.1775 mol) of 2,2-bis(3-amino-4-hydroxyphenyl)hexafluoropropane were added to 1 L of a flask having a mixer and thermometer mounted thereon, mixed and melted. Next, 35 g (0.4425 mol) of pyridine was added on the flask, and the manufactured solution was gradually dropped for 30 minutes, and mixed at room temperature for one hour. The resultant solution was added to 3 L of water, and the resultant deposit was filtered, washed, and vacuum dried to acquire 120 g of polyamidate E. In this instance, the acquired polyamidate E had a polystyrene-conversion average molecular weight of 16,200.

### Synthesis Example 9

### Iodonium Salts Synthesis

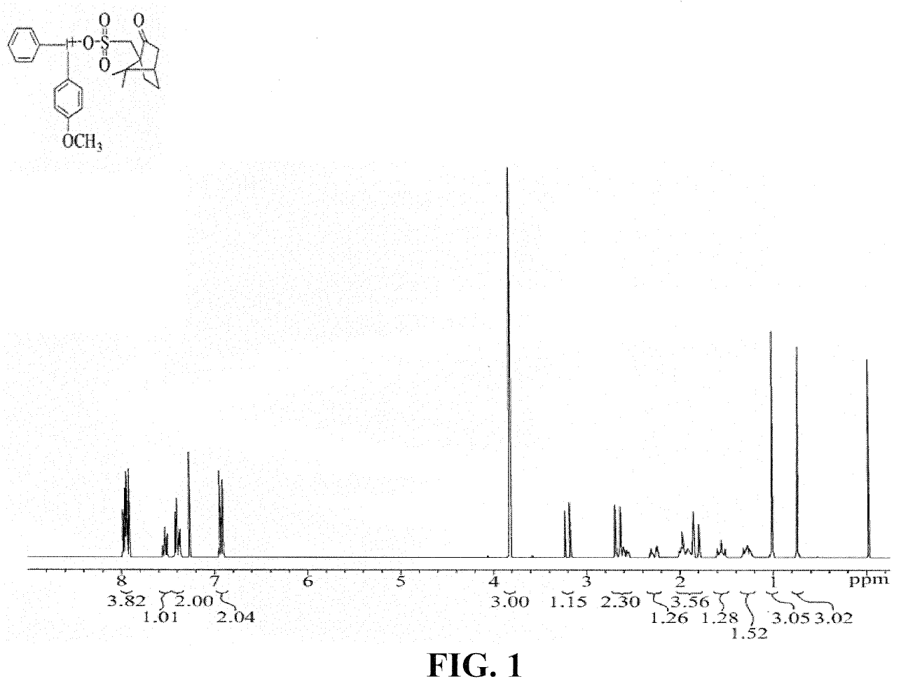

7.2 g of camphorsulfonic acid and 10 g of (diacetoxyiodo)benzene were dissolved in methylene chloride, a temperature of a reactor was reduced to 0° C., and 4 g of anisole was gradually dropped. Next, the reactor was heated to room temperature, and the resultant solution was mixed at room temperature for three hours. Next, the reaction mixture was washed three times with water, an organic layer was separated to remove the solvent. Next, the remained solid content was melted using a small amount of ethyl acetate, and a large amount of hexane was gradually added while mixing. In this instance, the generated deposit was filtered and dried to acquire 4-methoxyphenyl(phenyl)iodonium camphorsulfonate, and ¹H-NMR photograph thereof is shown in FIG. 1.

### Synthesis Example 10

### Amide Compound Synthesis of 2,2-bis(3-amino-4-hydroxyphenyl)hexafluoropropane and 5-norbornene-2,3-dicarboxylic anhydride

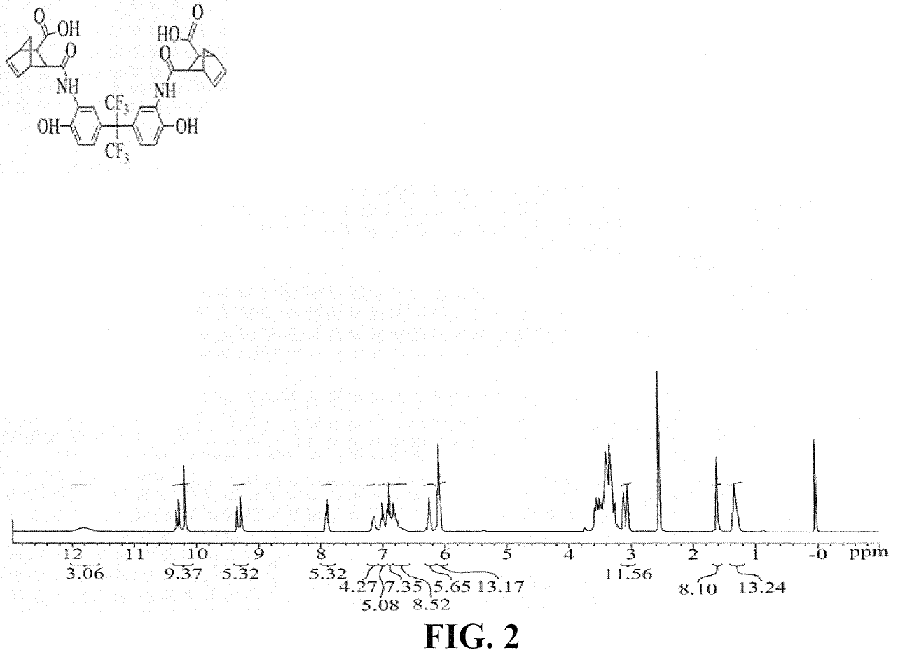

12 g of 2,2-bis(3-amino-4-hydroxyphenyl)hexafluoropropane and 10.7 g of 5-norbornene-2,3-dicarboxylic anhydride were dissolved in 90 g of NMP, 5.1 g of pyridine was added, and the resultant solution was mixed at the same temperature for three hours. The resultant solution was added to 2 L of 2% HCl, and the generated deposit was filtered, washed, and vacuum dried to acquire 20 g of amide compound. The ¹H-NMR photograph of the amide compound is shown in FIG. 2.

### Examples 1 to 15

### Manufacture of Positive Photosensitive Resin Compositions

The synthesized polyamide derivative, diazonaphthol compound, and various additives were dissolved in γ-butyrolactone to be 40 wt. %, and particulate foreign substances were removed using a filter of 0.5 μm to manufacture positive photosensitive resin compositions of Examples 1 to 15. In this instance, the element component ratio is shown in Table 1 below. As shown in Table 1, compounds represented by chemical formulas 7, 8, 9, and 10 below were respectively used for the additives 3, 4, 5, and 6. A small amount of polyether was used for the surfactant upon forming each of the positive photosensitive resin compositions, and is not shown in Table 1. Compounds represented by chemical formulas 11 (PAC 1) and 12 (PAC 2) below were used for the diazonaphthol compound. In this instance, a substitution degree of DNQ was 80%.

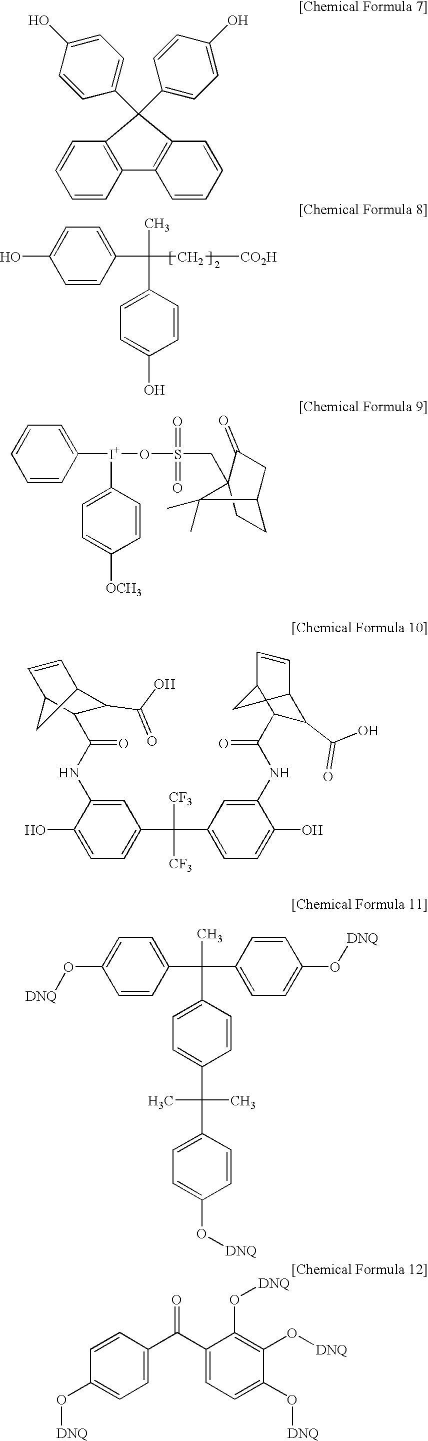

### Comparative Examples 1 to 5

### Manufacture of Positive Photosensitive Resin Compositions

Positive photosensitive resin compositions were manufactured in the same method as Examples 1 to 15 except without adding the compounds having the additives 3 to 6, and a component ratio thereof is shown in Table 1 below. For convenience of description, a small amount of the surfactant is not shown in Table 1.

TABLE 1

| | Polyamide | | | | | | | |
|---|---|---|---|---|---|---|---|---|
| | derivative | PAC | PAC | Additive | Additive | Additive | Additive | Solvent |
| | (g) | 1 (g) | 2 (g) | 3 (g) | 4 (g) | 5 (g) | 6 (g) | (g) |
| Example 1 | A, 29 | 6 | — | 5 | — | — | — | 60 |
| Example 2 | A, 29 | 6 | — | — | 5 | — | — | 60 |
| Example 3 | A, 29 | 6 | — | — | — | 5 | — | 60 |
| Example 4 | A, 24 | 6 | — | 5 | 5 | — | — | 60 |
| Example 5 | A, 29 | 4 | 2 | 5 | — | — | — | 60 |
| Example 6 | C, 29 | 6 | — | 5 | — | — | — | 60 |
| Example 7 | C, 29 | 6 | — | — | 5 | — | — | 60 |
| Example 8 | C, 29 | 6 | — | — | — | 5 | — | 60 |
| Example 9 | C, 24 | 6 | — | 5 | 5 | — | — | 60 |
| Example 10 | C, 29 | 4 | 2 | 5 | — | — | — | 60 |
| Example 11 | B, 28 | 6 | — | 5 | — | 1 | — | 60 |
| Example 12 | D, 29 | 6 | — | — | 5 | — | — | 60 |
| Example 13 | E, 28 | 6 | — | 5 | — | 1 | — | 60 |
| Example 14 | A, 26 | 4 | 2 | 5 | — | 1 | 2 | 60 |
| Example 15 | C, 26 | 4 | 2 | 5 | — | 1 | 2 | 60 |
| Comparative | A, 34 | 6 | — | — | — | — | — | 60 |
| Example 1 | | | | | | | | |
| Comparative | B, 34 | 6 | — | — | — | — | — | 60 |
| Example 2 | | | | | | | | |
| Comparative | C, 34 | 6 | — | — | — | — | — | 60 |
| Example 3 | | | | | | | | |
| Comparative | D, 34 | 6 | — | — | — | — | — | 60 |
| Example 4 | | | | | | | | |
| Comparative | E, 34 | 6 | — | — | — | — | — | 60 |
| Example 5 | | | | | | | | |

Characteristic Evaluation of Pattern Manufactured Using Positive Photosensitive Resin Compositions

Each positive photosensitive resin compositions of Examples 1 to 15 and Comparative Examples 1 to 5 was spin coated on a silicon wafer of 8 inches to have a thickness of 10 μm. In this instance, baking was performed at 130° C. for 60 seconds in order to completely remove the solvent. The coated wafer was exposed using an exposure apparatus, developed in about 2.38 wt % of tetramethylammonium hydroxide, and heated at 350° C. for 50 minutes to form a pattern.

The results obtained by measuring sensitivity at the time of exposing are shown in Table 2 below. Also, a layer thickness before and after exposing was measured using a nanospec, and a remaining rate calculated using the layer thickness is shown in Table 2 below. A resolution of the wafer was observed using a Scanning Electron Microscope (SEM), and the results are shown in Table 2 below. Also, pattern types were divided into the best, good, medium, and poor considering verticality and precision of the pattern type, and observed. The results are shown in Table 2 below. Also, scum remaining in a bottom of the developed parts was identified using SEM, and the results are shown in Table 2 below.

TABLE 2

| | | Re- | Reso- | | Occurrence/non- |
|---|---|---|---|---|---|
| | Sensitivity | maining | lution | Pattern | occurrence of |
| | (mJ/cm²) | rate (%) | (μm) | type | scum |
| Example 1 | 580 | 83 | 5 | Medium | Nonoccurrence |
| Example 2 | 510 | 71 | 4 | Best | Nonoccurrence |
| Example 3 | 820 | 95 | 4 | Good | Occurrence in |
| | | | | | small amount |
| Example 4 | 400 | 80 | 5 | Good | Nonoccurrence |
| Example 5 | 560 | 81 | 4 | Good | Nonoccurrence |
| Example 6 | 580 | 79 | 4 | Good | Nonoccurrence |
| Example 7 | 510 | 65 | 4 | Good | Nonoccurrence |
| Example 8 | 820 | 92 | 4 | Good | Nonoccurrence |
| Example 9 | 400 | 75 | 4 | Best | Nonoccurrence |
| Example 10 | 560 | 75 | 4 | Good | Nonoccurrence |
| Example 11 | 540 | 73 | 4 | Good | Nonoccurrence |
| Example 12 | 510 | 77 | 5 | Good | Nonoccurrence |
| Example 13 | 420 | 75 | 4 | Best | Nonoccurrence |
| Example 14 | 430 | 80 | 4 | Best | Nonoccurrence |
| Example 15 | 400 | 78 | 4 | Best | Nonoccurrence |
| Comparative | 660 | 80 | 7 | Poor | Occurrence in |
| Example 1 | | | | | small amount |
| Comparative | 550 | 75 | 6 | Medium | Nonoccurrence |
| Example 2 | | | | | |
| Comparative | 680 | 88 | 6 | Medium | Nonoccurrence |
| Example 3 | | | | | |
| Comparative | 740 | 93 | 8 | Poor | Nonoccurrence |
| Example 4 | | | | | |
| Comparative | 430 | 81 | 5 | Medium | Nonoccurrence |
| Example 5 | | | | | |

As shown in Table 2, in the case where the pattern was formed using the positive photosensitive resin compositions according to the present examples, the sensitivity, remaining rate, and pattern type were relatively excellent in comparison with comparative examples, and occurrence of the scum was rarely observed.

Although a few exemplary embodiments of the present invention have been shown and described, the present invention is not limited to the described exemplary embodiments. Instead, it would be appreciated by those skilled in the art that changes may be made to these exemplary embodiments without departing from the principles and spirit of the invention, the scope of which is defined by the claims and their equivalents.

What is claimed is:

1. A positive photosensitive resin composition, comprising:
100 parts by weight of a polyamide derivative;
5 to 30 parts by weight of a photosensitive compound; and
0.5 to 20 parts by weight of at least one additive selected from chemical formulas (1) to (4) below 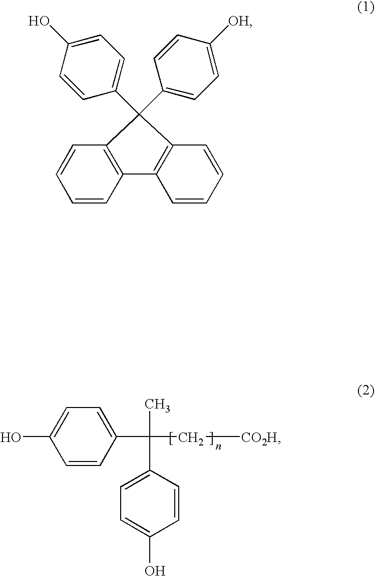
wherein n is an integer of 2 to 6, 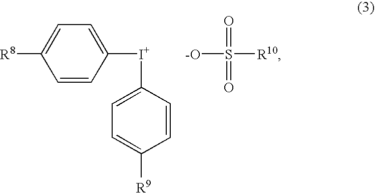
wherein R⁸ and R⁹ are independently selected from H and C₁₋₁₀ organic group, and R¹⁰ is a C₁₋₂₀ alkyl group or a C₁₋₂₀ aryl group, and

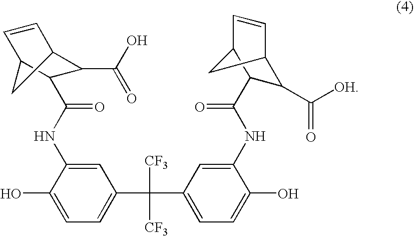

2. The composition of claim 1, further comprising:
0.5 to 10 parts by weight of an agent for improving adhesiveness; and
0.005 to 0.05 parts by weight of a surfactant.

3. The composition of claim 1, wherein the polyamide derivative is 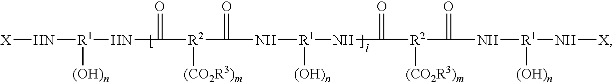
wherein R¹ and R² are independently selected from organic group (II) to organic group (VI) each with 2 or more carbon atoms,
R³ is selected from H and a C₁₋₁₀ organic group,
l is an integer of 10 to 1,000,
n and m are independently selected from integers of 0 to 2, in which n+m>0, and
X is selected from H and a C₂₋₃₀ organic group.

4. The composition of claim 3, wherein R¹ is selected from at least one of chemical formulas below: 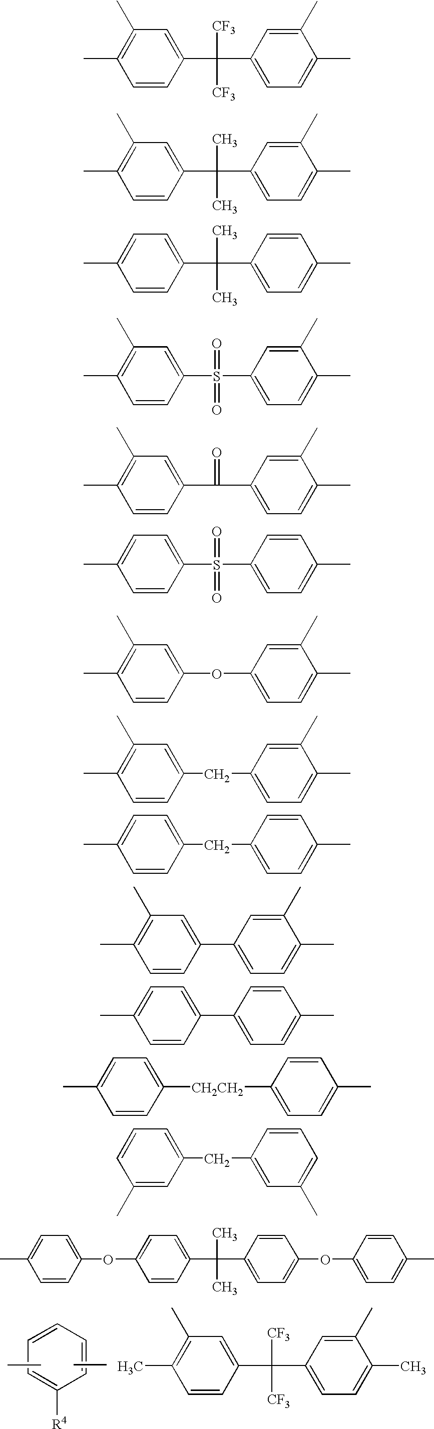 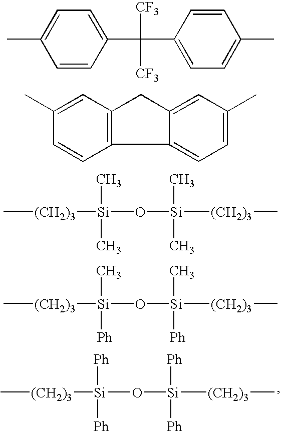
wherein R⁴ is selected from H, halogen, a hydroxy group, a carboxyl group, a thiol group and a C₁₋₁₀ organic group.

5. The composition of claim 3, wherein R² is selected from at least one of chemical formulas below: 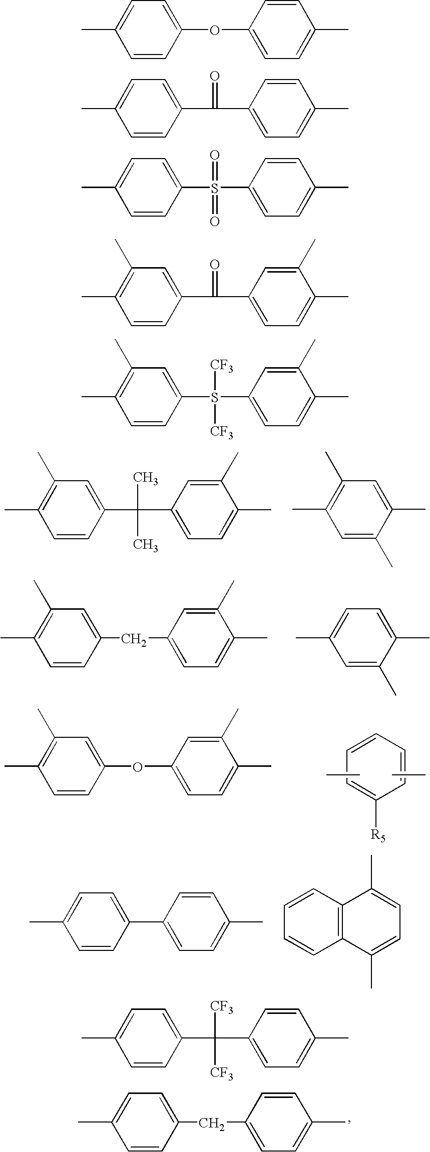
wherein R⁵ is selected from H, halogen, a hydroxy group, an ether group, a thiol group and a C₁₋₁₀ organic group.

6. The composition of claim 3, wherein X is selected from at least one of chemical formulas below: 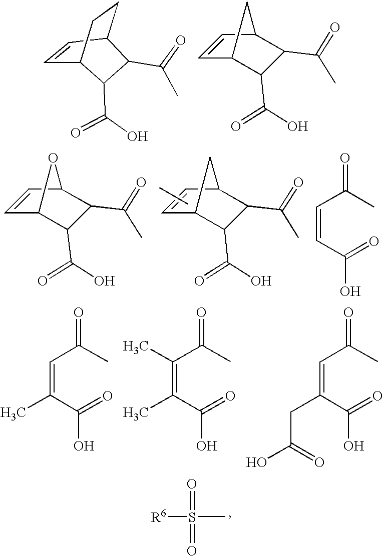
wherein R⁶ is a C₁₋₁₀ organic group comprising an alkyl group or an aryl group.

7. The composition of claim 1, wherein the photosensitive compound is a diazonaphthol compound.

8. The composition of claim 7, wherein the diazonaphthol compound is 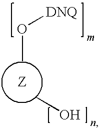
wherein n and m are independently selected from integers of 0 to 5, in which n+m>0, 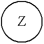
is a C₁₂₋₄₀ aryl group, and DNQ is

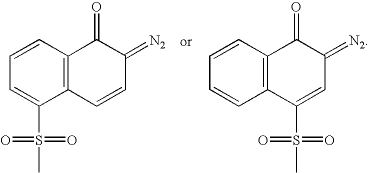

9. The composition of claim 8, wherein the diazonaphthol compound is selected from at least one of chemical formulas below: 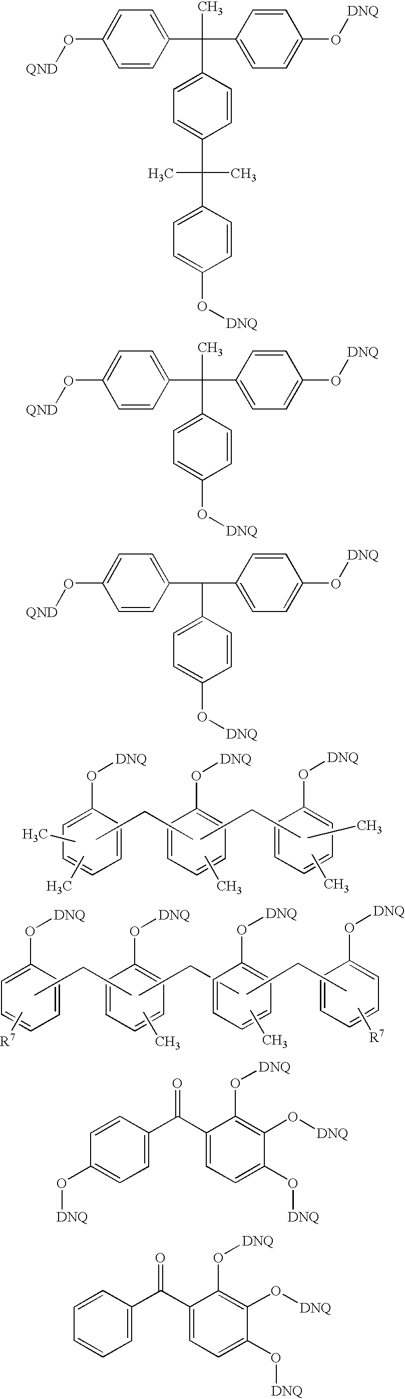 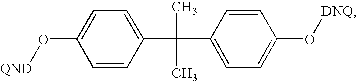
wherein DNQ is H, 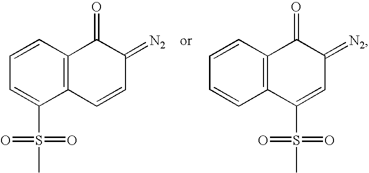
each of the diazonaphthol compound comprises at least one of 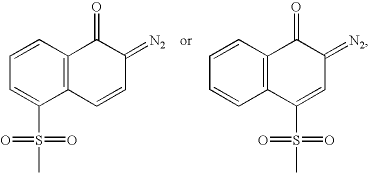
and R⁷ is selected from H, a methyl group and —O-DNQ group.

10. The composition of claim 2, wherein the agent for improving adhesiveness is selected from at least one of groups consisting of vinyltrimethoxysilane, [3-(2-aminoethylamino)propyl]trimethoxysilane, 3-aminopropyltrimethoxysilane, N-methylaminopropyltrimethoxysilane, 3-glycidoxypropyltrimethoxysilane, 3-glycidoxypropyltriethoxysilane, 2-(3,4-epoxycyclohexyl)ethyltrimethoxysilane, 3-methacryloxypropyltrimethoxysilane, 3-mercaptopropyltrimethoxysilane, N-(1,3-dimetheylbutylidene)-3-(triethoxysilane)-1-propanamine, N,N-bis(3-trimethoxysilyl)propylethylamine, N-(3-trimethoxysilylpropyl)pyrrole, ureidopropyltrimethoxysilane, (3-triethoxysilylpropyl)-t-butylcarbamate, N-phenylaminopropyltrimethoxysilane, and 3-isocyanatepropyltrimethoxysilane.

11. A method for forming a pattern, comprising:
coating the composition for the positive photosensitive resin of claim 1 on a substrate, and drying the coated composition to form a photoresist layer;
selectively exposing the photoresist layer;
developing the exposed photoresist layer to form a photoresist pattern; and
heating the photoresist pattern.

12. The method of claim 11, wherein the substrate is a substrate used for manufacturing a semiconductor.

13. The method of claim 11, wherein the selectively exposing is performed using an i-line ray, h-line ray or g-line ray.

14. A semiconductor having the photoresist pattern obtained by the method of claim 11 acting as an interlayer dielectric or passivation layer.
